(19) United States
(12) Patent Application Publication
(10) Pub. No.: US 2024/0431117 A1
(43) Pub. Date: Dec. 26, 2024

(54) MEMORY WITH ONE ACCESS TRANSISTOR COUPLED TO MULTIPLE CAPACITORS

(71) Applicant: Intel Corporation, Santa Clara, CA (US)

(72) Inventors: Abhishek A. Sharma, Portland, OR (US); Wilfred Gomes, Portland, OR (US); Tahir Ghani, Portland, OR (US); Anand S. Murthy, Portland, OR (US)

(73) Assignee: Intel Corporation, Santa Clara, CA (US)

(21) Appl. No.: 18/338,404

(22) Filed: Jun. 21, 2023

(51) Int. Cl. H10B 53/30

(52) U.S. Cl. CPC H10B 53/30

(57) ABSTRACT

IC devices implementing memory with one access transistor coupled to multiple capacitors are disclosed. An example IC device includes a support structure (e.g., a substrate), an access transistor over the support structure, the access transistor having a region that is either a source region or a drain region, and a plurality of capacitors where at least two or more of the capacitors are in different layers above the access transistor. First capacitor electrodes of the plurality of capacitors are coupled to the region, and second capacitor electrodes of the plurality of capacitors are coupled to respective electrically conductive lines. IC devices implementing memory with one access transistor coupled to multiple capacitors as described herein may be used to address the scaling challenges of conventional 1T-1C memory technology and enable high-density embedded memory compatible with advanced CMOS processes.

### BACKGROUND

Embedded memory is important to the performance of modern system-on-a-chip (SoC) technology. Low-power and high-density embedded memory is used in many different computer products and further improvements are always desirable.

### BRIEF DESCRIPTION OF THE DRAWINGS

Embodiments will be readily understood by the following detailed description in conjunction with the accompanying drawings.

FIG. 1 provides a block diagram of an integrated circuit (IC) device implementing memory with one access transistor coupled to multiple capacitors, according to some embodiments of the present disclosure.

FIG. 2 provides an electric circuit diagram of a memory unit with an access transistor and multiple capacitors coupled to respective platelines, according to some embodiments of the present disclosure.

FIG. 3 provides an electric circuit diagram of an IC device where each plateline is shared among multiple wordlines and, in each memory unit, different ones of multiple hysteretic capacitors are coupled to different platelines, according to some embodiments of the present disclosure.

FIG. 4 provides an electric circuit diagram of an IC device where each plateline is shared among multiple bitlines and, in each memory unit, different ones of multiple hysteretic capacitors are coupled to different platelines, according to some embodiments of the present disclosure.

FIGS. 5A and 5B illustrate a cross-sectional side view and a top-down view of an example IC device with an access transistor and multiple capacitors coupled to respective platelines, according to some embodiments of the present disclosure.

FIGS. 6A and 6B illustrate a cross-sectional side view and a top-down view of an example IC device with an access transistor and multiple capacitors coupled to respective platelines, according to other embodiments of the present disclosure.

FIG. 7 provides top views of a wafer and dies that may include one or more IC devices implementing memory with one access transistor coupled to multiple capacitors in accordance with any of the embodiments disclosed herein.

FIG. 8 is a cross-sectional side view of an IC package that may include one or more IC devices implementing memory with one access transistor coupled to multiple capacitors in accordance with any of the embodiments disclosed herein.

FIG. 9 is a cross-sectional side view of an IC device assembly that may include one or more IC devices implementing memory with one access transistor coupled to multiple capacitors in accordance with any of the embodiments disclosed herein.

FIG. 10 is a block diagram of an example computing device that may include memory with one access transistor coupled to multiple capacitors in accordance with any of the embodiments disclosed herein.

FIG. 11 is a block diagram of an example processing device that may include memory with one access transistor coupled to multiple capacitors in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC devices implementing memory with one access transistor coupled to multiple capacitors as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

Some memory devices may be considered “standalone” devices in that they are included in a chip that does not also include compute logic (where, as used herein, the term “compute logic devices” or simply “compute logic” or “logic devices,” refers to IC components, e.g., transistors, for performing computing/processing operations). Other memory devices may be included in a chip along with compute logic and may be referred to as “embedded” memory devices. Using embedded memory to support compute logic may improve performance by bringing the memory and the compute logic closer together and eliminating interfaces that increase latency. Various embodiments of the present disclosure relate to embedded memory arrays, as well as corresponding methods and devices.

Access transistors have been used in the past to realize memory where each memory cell includes one capacitor for storing a memory state (e.g., logical “1” or “0”) of the cell and an access transistor controlling access to the cell (e.g., access to write information to the cell or access to read information from the cell). Such a memory cell may be referred to as a “1T-1C memory cell,” highlighting the fact that it uses one access transistor (i.e., “1T” in the term “1T-1C memory cell”) and one capacitor (i.e., “1C” in the term “1T-1C memory cell”). The capacitor of a 1T-1C memory cell may be coupled to either a source or a drain (S/D) terminal/region of the access transistor (e.g., to the source terminal/region of the access transistor), while the other S/D terminal/region of the access transistor (e.g., to the drain terminal/region) may be coupled to a bitline, and a gate terminal of the access transistor may be coupled to a wordline. Since such a memory cell can be fabricated with as little as a single access transistor, it can provide higher density and lower standby power versus some other types of memory in the same process technology. In some implementations, capacitors of 1T-1C memory cells may be implemented using a dielectric, non-ferroelectric material as a capacitor insulator. In other implementations, capacitors of 1T-1C memory cells may be implemented with capacitor insulators including a ferroelectric material instead of, or in addition to, a conventional dielectric material, thus realizing ferroelectric 1T-1C memory cells. Inventors of the present disclosure realized that memory arrays implementing 1T-1C memory cells may have limitations in terms of, e.g., the number of active memory layers, memory density, and fabrication approaches.

Embodiments of the present disclosure may improve on at least some of the challenges and issues of existing memory arrays by increasing the number of active memory layers, to generate a vertically stacked memory using fewer masks and at a lower cost. In particular, IC devices implementing memory with one access transistor coupled to multiple capacitors are disclosed. An example IC device includes a support structure (e.g., a substrate, a wafer, a die, or a chip), an access transistor over the support structure, the access transistor having a region that is either a source region or a drain region, and a plurality of capacitors where at least two or more of the capacitors are in different layers above the access transistor. In such an IC device, first capacitor electrodes of the plurality of capacitors are coupled (e.g., directly connected) to the region, and second capacitor electrodes of the plurality of capacitors are coupled (e.g., directly connected) to respective (i.e., different) electrically conductive lines (e.g., platelines). In such an IC device, a single access transistor is coupled to multiple capacitors and is shared among these capacitors. An individual one of the plurality of capacitors may store a memory state, thus realizing a memory cell of a memory array. One access transistor coupled to a plurality of capacitors may be referred to as a “memory unit” of the IC device. Coupling the second capacitor electrodes of the multiple capacitors of the memory unit to respective electrically conductive lines allows selecting all of the capacitors for performing READ and/or WRITEs operation when the access transistor is ON (e.g., when current may be conducted between source and drain terminals of the access transistor). Incorporating at least some of the capacitors and platelines of a memory unit in different layers with respect to a support structure may allow significantly increasing density of memory cells in a memory array having a given footprint area (the footprint area being defined as an area in a plane of the support structure, or a plane parallel to the plane of the support structure, i.e., the x-y plane of the example coordinate system shown in the present drawings), or, conversely, allow significantly reducing the footprint area of the memory array with a given density of memory cells. IC devices implementing memory with one access transistor coupled to multiple capacitors as described herein may be used to address the scaling challenges of conventional 1T-1C memory technology and enable high-density embedded memory compatible with advanced complementary metal-oxide-semiconductor (CMOS) processes. Other technical effects will be evident from various embodiments described here.

An example memory unit may include one access transistor coupled to N capacitors. An example IC device may include a memory array of M of such memory units, as well as W wordlines, B bitlines, and P platelines, where any of variables N, M, W, B, and P may be any integer greater than 1. An IC device may be provided on a support structure such as a substrate, a die, a wafer, or a chip, and, in various arrangements disclosed herein, various capacitors and platelines may be arranged in different layers with respect to the support structure than layers in which wordlines and/or bitlines are implemented, thus realizing a three-dimensional (3D) stacked architecture of the memory array.

Memory arrangements described herein, in particular memory units where one access transistor is coupled to multiple capacitors, may be particularly suitable for hysteretic memory. Hysteretic memory refers to a memory technology employing hysteretic materials or arrangements, where a material or an arrangement may be described as hysteretic if it exhibits the dependence of its state on the history of the material (e.g., on a previous state of the material). Ferroelectric (FE) and antiferroelectric (AFE) materials are one example of hysteretic materials. Layers of different materials arranged in a stack to exhibit charge-trapping phenomena is one example of a hysteretic arrangement. Hysteretic memories have the potential for adequate non-volatility, short programming time, low power consumption, high endurance, and high-speed writing. In addition, hysteretic memories may be manufactured using processes compatible with the standard CMOS technology. Therefore, over the last few years, these types of memories have emerged as promising candidates for many growing applications.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, despite the fact that there is typically no iron (Fe) present in FE or AFE materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a voltage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the amount of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

In some embodiments, the multiple capacitors coupled to one access transistors as described herein may be hysteretic capacitors. As used herein, a capacitor is referred to as a “hysteretic capacitor” if, instead of or in addition to a conventional dielectric material, the capacitor includes a hysteretic material or a hysteretic arrangement as a capacitor insulator that separates first and second capacitor electrodes.

In the following, descriptions are provided with respect to capacitors and platelines provided in different layers above a support structure, compared to the layers in which wordlines and bitlines are provided (i.e., the capacitors, platelines, wordlines, and bitlines are described to be in certain layers above a given side of the support structure, e.g., above the front side of the support structure). However, in general, these descriptions are equally applicable to embodiments where some of the capacitors, platelines, wordlines, and bitlines are provided in one or more layers on the front side of the support structure and other ones are provided in one or more layers on the back side of the support structure, all of which embodiments being within the scope of the present disclosure. In the context describing various layers in the present disclosure, the term “above” may refer to a layer being further away from a support structure of an IC device, while the term “below” refers to a layer being closer to the support structure. Although descriptions of the present disclosure may refer to logic devices or memory cells provided in a given layer, each layer of the IC devices described herein may also include other types of devices besides logic or memory devices described herein. For example, in some embodiments, IC devices implementing memory with one access transistor coupled to multiple capacitors cells may also include hysteretic memory cells, non-hysteretic memory cells, or any other type of memory cells, or components other than memory cells (e.g., logic devices such as logic transistors) in any of the layers.

As used herein, a “memory state” (or, alternatively, a “logic state,” a “state,” or a “bit” value) of a memory cell refers to one of a finite number of states that the cell can have, e.g., logic states “1” and “0.” When any of the memory cells as described herein use a hysteretic material such as a FE or an AFE material, in some embodiments, a logic state of the memory cell may be represented simply by presence or absence of polarization of a FE or an AFE material in a certain direction (for example, for a two-state memory where a memory cell can store one of only two logic states—one logic state representing the presence of polarization in a certain direction and the other logic state representing the absence of polarization in a certain direction). In other embodiments of memory cells that include hysteretic materials such as FE or AFE materials, a logic state of a memory cell may be represented by the amount of polarization of a FE or an AFE material in a certain direction (for a multi-state memory where a memory cell can store one of three or more logic states, where different logic states represent the presence of different amounts of polarization in a certain direction). When any of the memory cells as described herein use a charge-trapping hysteretic arrangement, in some embodiments, a logic state of a memory cell may be represented simply by presence or absence of charge trapped in a charge-trapping hysteretic arrangement (for example, for a two-state memory where a memory cell can store one of only two logic states—one logic state representing the presence of charge and the other logic state representing the absence of charge). In other embodiments of memory cells that include charge-trapping hysteretic arrangements, a logic state of a memory cell may be represented by the amount charge trapped in a charge-trapping hysteretic arrangement (for example, for a multi-state memory where a memory cell can store one of three or more logic states, where different logic states represent the presence of different amounts of trapped charges). As used herein, “READ” and “WRITE” memory access or operations refer to, respectively, determining/sensing a logic state of a memory cell and programming/setting a logic state of a memory cell.

In the following detailed description, various aspects of the illustrative implementations may be described using terms commonly employed by those skilled in the art to convey the substance of their work to others skilled in the art. For example, some descriptions may refer to a particular S/D region of a transistor being either a source region or a drain region. However, unless specified otherwise, which region of a transistor is considered to be a source region and which region is considered to be a drain region is not important because, as is common in the field of FETs, designations of source and drain are often interchangeable. Therefore, descriptions of some illustrative embodiments of the source and drain regions provided herein are applicable to embodiments where the designation of source and drain regions may be reversed. Furthermore, in context of S/D regions, the term “region” may be used interchangeably with the terms “contact” and “terminal” of a transistor.

As used herein, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

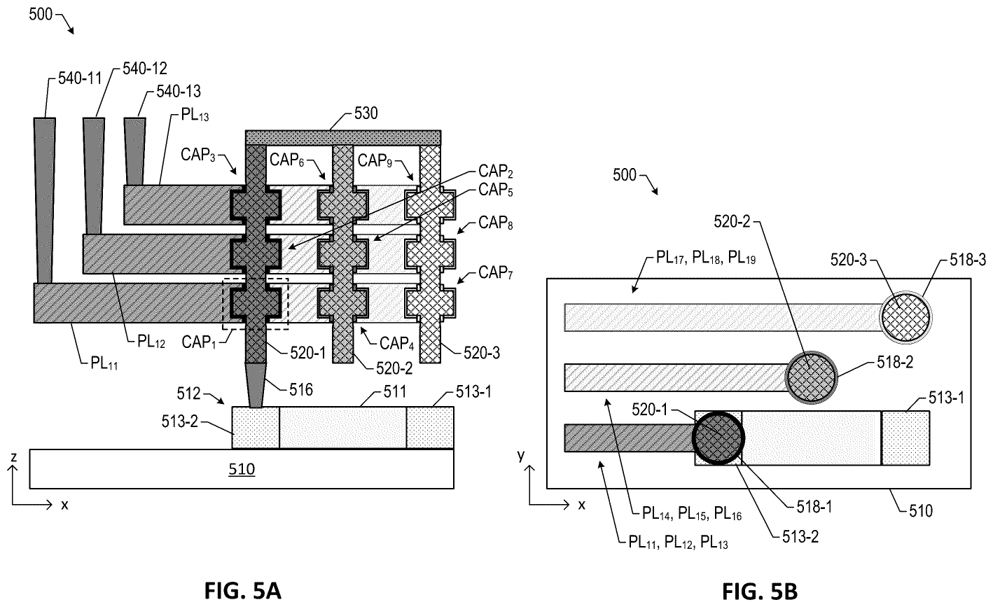

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, analogous elements designated in the present drawings with different reference numerals after a dash, e.g., capacitors 106-1, 106-2, and so on may be referred to together without the reference numerals after the dash, e.g., as “capacitors 106.” Similarly, a collection of drawings designated with a letter, e.g., FIGS. 5A and 5B, may be referred to together without the letter, e.g., as “FIG. 5.” In order to not clutter the drawings, if multiple instances of certain elements are illustrated, only some of the elements may be labeled with a reference sign.

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC devices implementing memory with one access transistor coupled to multiple capacitors as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices implementing memory with one access transistor coupled to multiple capacitors as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

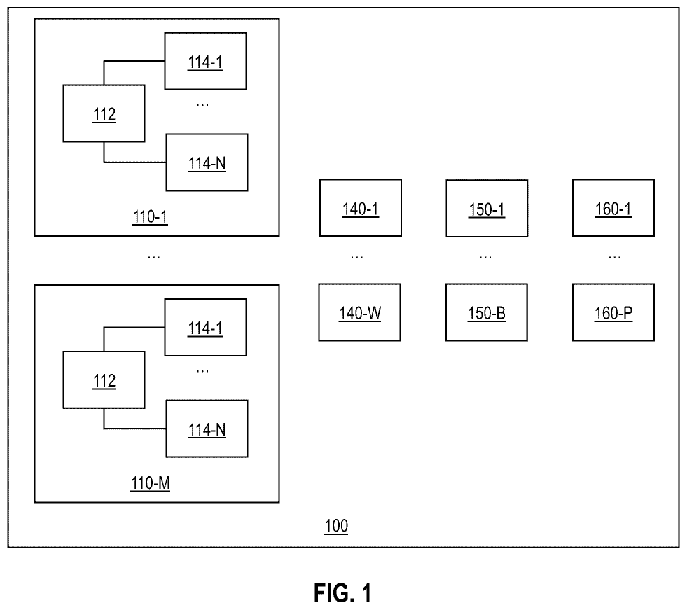

FIG. 1 provides a block diagram of an IC device 100 implementing memory with one access transistor coupled to multiple capacitors, according to some embodiments of the present disclosure. As shown in FIG. 1, the IC device 100 includes M memory units 110, labeled as memory units 110-1 through 110-M. Each of the memory units 110 includes an access transistor 112 and a plurality of capacitors 114 coupled to the access transistor 112. The capacitors 114 of each of the memory units 110 are labeled in FIG. 1 as capacitors 114-1 through 114-N, although, in general, different memory units 110 may include different number of capacitors (i.e., unlike the illustration of FIG. 1 may suggest, in other embodiments of the IC device 100, not all of the memory units 110 include N capacitors 114). As further shown in FIG. 1, the IC device 100 may also include W wordlines 140, labeled as wordlines 140-1 through 140-W, B bitlines 150, labeled as bitlines 150-1 through 150-B, and P platelines 160, labeled as platelines 160-1 through 160-P.

In general, any of variables N, M, W, B, and P may be any integer greater than 1 and may be different from one another, although in some specific embodiments two of more of these variables may be of the same value (e.g., the number of wordlines 140 may be equal to the number of bitlines 150, i.e., W=B in some embodiments). In some embodiments, the value of one of these variables depends on the value of one or more of the other ones of these variables (e.g., in various embodiments, the number of platelines 160 may depend on one or more of the number of wordlines 140, the number of bitlines 150, and the number of capacitors 114 in each of the memory units 110). The following convention is used in some of the subsequent drawings and in the present descriptions to refer to different instances of the wordlines 140, bitlines 150, and platelines 160 of the IC device 100. An individual wordline 140 is labeled in some of the subsequent drawings as WLᵢ, where i is an integer between 1 and W, identifying one of the W wordlines 140. An individual bitline 150 is labeled in some of the subsequent drawings as BLⱼ, where j is an integer between 1 and B, identifying one of the B bitlines 150. An individual capacitor 114 within a given memory unit 110 is labeled in some of the subsequent drawings as CAPₖ, where k is an integer between 1 and N, identifying one of the N capacitors 114. An individual plateline 160 is labeled in some of the subsequent drawings with one or two indices that may depend on the arrangement of the wordlines 140 and the bitlines 150, and to which one of the N capacitors 114 the plateline 160 is coupled to, such one or two indices identifying one of the P platelines 160. A three-dimensional tensor may then be defined, where indices i, j, and k of a given element of the tensor uniquely identify each of the capacitors 114 of the IC device 100 in terms of a unique combination of a wordline 140-i and a bitline 150-j to which the memory unit 110 of a given capacitor 114 belongs to, in combination with a unique identification of the capacitor 114-k within that memory unit 110. Because each capacitor 114 may be used to store a logic state, thus serving as a memory cell of the IC device 100, such a tensor may be used to uniquely identify each memory cell of the IC device 100.

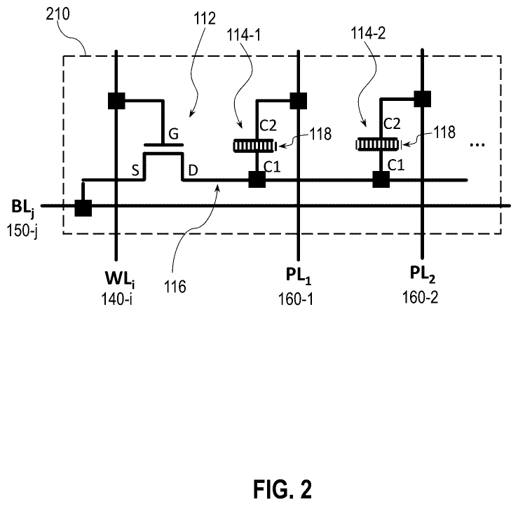

FIG. 2 provides an electric circuit diagram of a memory unit 210 with an access transistor and multiple capacitors coupled to different platelines, according to some embodiments of the present disclosure. Each of the memory units 110 of the IC device 100 may be implemented as the memory unit 210 as shown in FIG. 2.

As shown in FIG. 2, the access transistor 112 may be a FET, having a gate terminal, a source terminal, and a drain terminal, labeled in the example of FIG. 2 as terminals G, S, and D, respectively. As further shown in FIG. 2, the gate terminal of the access transistor 112 may be coupled to a wordline 140-i, one of the source or drain regions (e.g., a first S/D region) of the access transistor 112 may be coupled to a bitline 150-j, and the other one of the source or drain regions (e.g., a second S/D region) of the access transistor 112 may be coupled, via an intermediate node 116, to a first capacitor electrode (labeled in FIG. 2 as “C1”) of each of the N capacitors 114 of the memory unit 210 (only two such capacitors are shown in FIG. 2, but the possibility of additional capacitors 114 is illustrated in FIG. 2 with three dots to the right side of the capacitor 114-2). As is commonly known, designations of “source” and “drain” may be interchangeable in transistors. Therefore, while the example of FIG. 2 illustrates that the access transistor 112 is coupled to each of the N capacitors 114 by its drain terminal, in other embodiments, any one of a source or a drain terminal of the access transistor 112 may be coupled to the first capacitor electrode of each of the N capacitors 114. A source and a drain terminal of a transistor is sometimes referred to in the following as a “transistor terminal pair” and a “first terminal” of a transistor terminal pair is used to describe, for the access transistor 112, the terminal that is connected to the BL, while a “second terminal” is used to describe the source or drain terminal of the access transistor that is connected to the first capacitor electrode of each of the N capacitors 114.

As further shown in FIG. 2, second capacitor electrodes (labeled in FIG. 2 as “C2”) of different ones of the N capacitors 114 of the memory unit 210 are coupled to respective (i.e., different) platelines 160. In particular, FIG. 2 shows that the second capacitor electrode of the capacitor 114-1 is coupled to the plateline 160-1, the second capacitor electrode of the capacitor 114-2 is coupled to the plateline 160-2, and so on.

In some embodiments, the access transistors 112 of the IC device 100 may be implemented as transistors having a non-planar architecture. Examples of transistors having a non-planar architecture include double-gate transistors, trigate transistors, FinFETs, and nanoribbon-based transistors. In comparison to a planar architecture where the transistor channel has only one confinement surface, a non-planar architecture is any type of architecture where the transistor channel has more than one confinement surfaces. A confinement surface refers to a particular orientation of the channel surface that is confined by the gate field. Non-planar transistors potentially improve performance relative to transistors having a planar architecture, such as single-gate transistors.

Each of the WL 140, the BL 150, and the PL 160, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 2 further illustrates that each of the capacitors 114 includes a capacitor insulator 118 between the first and second capacitor electrodes. In some embodiments, the capacitor insulator 118 may be a non-hysteretic dielectric material (i.e., a regular dielectric material used in conventional dielectric (i.e., not hysteretic) capacitors). In other embodiments, instead of, or in addition to, a regular dielectric material used in conventional dielectric (i.e., not hysteretic) capacitors, the capacitor insulator 118 of at least some of the capacitors 114 may include a hysteretic material or a hysteretic arrangement, which, together, may be referred to as a “hysteretic element.” In such embodiments, the capacitors 114 may be described as “hysteretic capacitor.” The hysteretic element used as the capacitor insulator 118 of any of the capacitors 114 may have a thickness that may, in some embodiments, be between about 0.5 nanometers and 10 nanometers, including all values and ranges therein (e.g., between about 1 and 8 nanometers, or between about 0.5 and 5 nanometers).

In some embodiments, the hysteretic element of the capacitor insulator 118 may be provided as a layer of a FE or an AFE material. Such an FE/AFE material may include one or more materials that can exhibit sufficient FE/AFE behavior even at thin dimensions, e.g., such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic elements of the capacitor insulators 118 and are within the scope of the present disclosure.

In other embodiments, the hysteretic element of the capacitor insulator 118 may be provided as a stack of alternating layers of materials that can trap charges. In some such embodiments, the stack may be a two-layer stack, where one layer is a charge-trapping layer and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. Such defects are very detrimental to operation of logic devices and, therefore, typically, deliberate steps need to be taken to avoid presence of the defects. However, for memory devices, such defects are desirable because charge-trapping may be used to represent different memory states of a memory cell.

In some embodiments of the hysteretic element of the capacitor insulator 118 being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

In various embodiments of the hysteretic element of the capacitor insulator 118 being provided as a stack of alternating layers of materials that can trap charges, a thickness of each layer the stack may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element of the capacitor insulator 118 provided as a stack of alternating layers of materials that can trap charges (i.e., a hysteretic arrangement) may be between about 1 and 10 nanometers, e.g., between about 2 and 8 nanometers, e.g., about 6 nanometers.

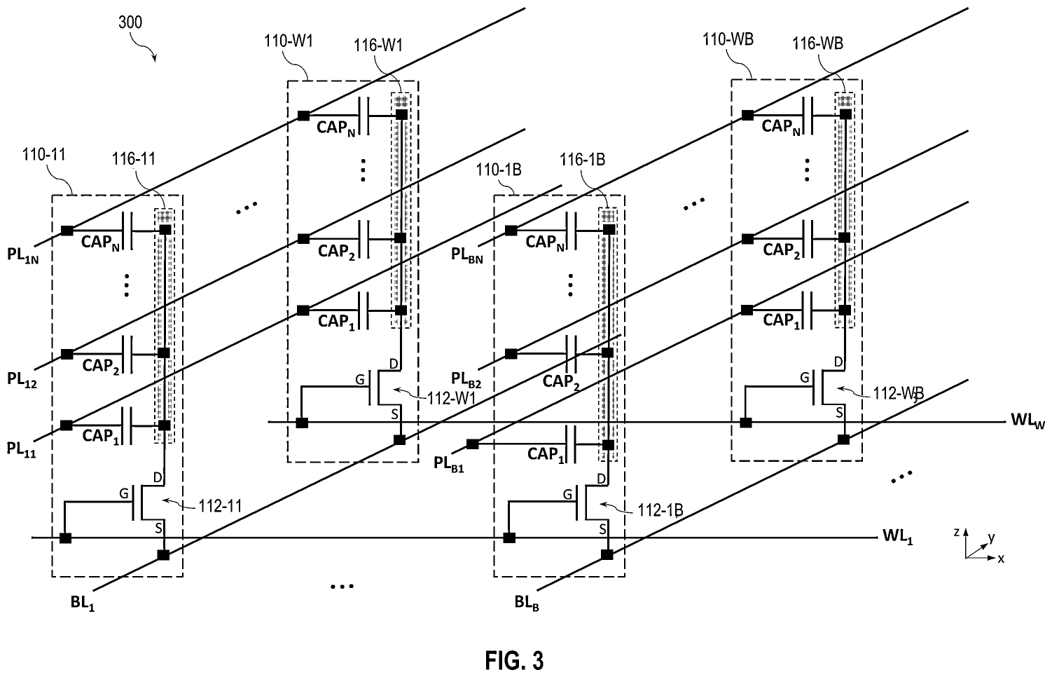

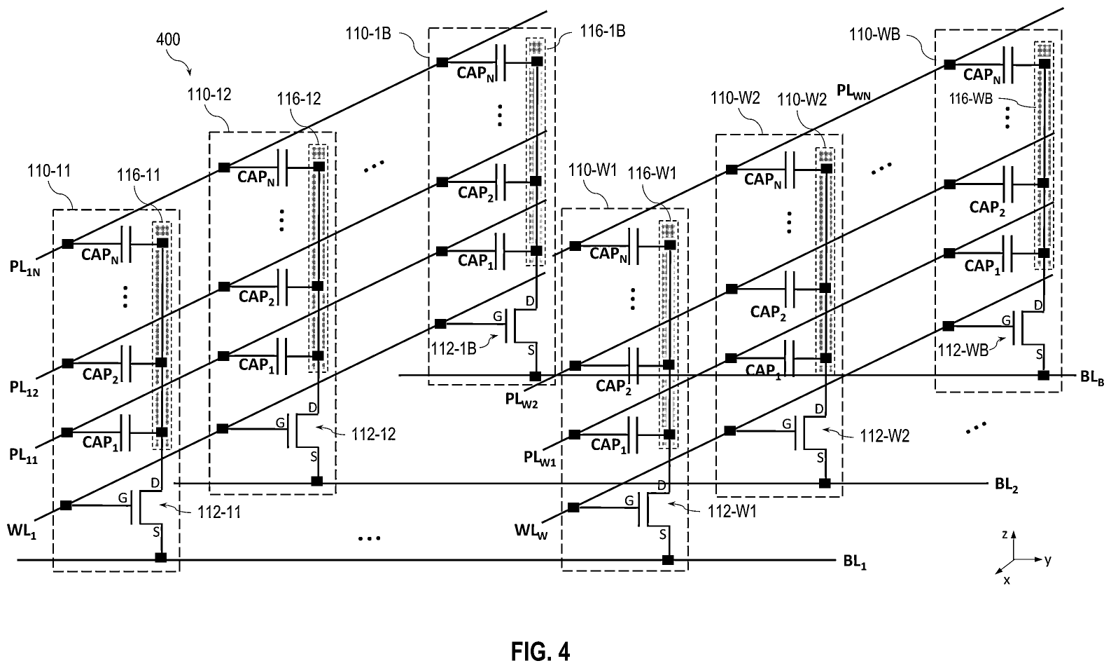

FIGS. 3-4 provide electric circuit diagrams of example arrangements of various components of the IC device 100.

What FIGS. 3-4 have in common is that each of the memory units 110 (in particular, the access transistor 112 of each of the memory units 110) is coupled to a unique combination of one of the wordlines 140 and one of the bitlines 150. Since there are W wordlines 140 and B bitlines 150, this means that the IC device 100 illustrated in each of FIGS. 3-4 include WxB memory units 110 (i.e., M=WxB for the illustrations of FIGS. 3-4). Different memory units 110 may be coupled to a single wordline 140 and such memory units 110 may be referred to as belonging to a single “row” of memory units. Different memory units 110 may be coupled to a single bitline 150 and such memory units 110 may be referred to as belonging to a single “column” of memory units. Since each of the memory units 110 is coupled to a unique combination of a wordline 140-i and a bitline 150-j, individual memory units 110 are labeled in FIGS. 3-4 as memory units 110-ij and access transistors 112 within those memory units are labeled as transistors 112-ij, where i identifies the wordline 140-i to which the memory unit 110-ij is coupled (i.e., i identifies the row to which the memory unit 110 belongs) and j identifies the bitline 150-j to which the memory unit 110-ij is coupled (i.e., j identifies the column to which the memory unit 110 belongs). Similarly, intermediate nodes 116 of the individual memory units 110 are labeled in FIGS. 3-4 as 116-ij.

What FIGS. 3-4 also have in common is that each memory unit 110 is illustrated in FIGS. 3-4 to have N capacitors 114, which means that the IC devices 100 illustrated in each of FIGS. 3-4 include WxBxN memory cells, when each capacitor 114 is considered to be a memory cell. Furthermore, FIGS. 3-4 also share that N capacitors 114 of a given memory unit 110 are coupled to different platelines 160. Where FIGS. 3-4 differ is whether a single plateline 160 is shared among multiple wordlines 140 (e.g., among all W of the wordlines 140, as shown in FIG. 3) or whether a single plateline 160 is shared among multiple bitlines 150 (e.g., among all B of the bitlines 150, as shown in FIG. 4).

Each of FIGS. 3-4 illustrates individual capacitors 114 of the IC device units 110 arranged in a 3D array in different orientations with respect to wordlines 140, bitlines 150, and platelines 160. In particular, each of FIGS. 3-4 illustrates W wordlines 140 extending along an x-axis of an example coordinate system shown in these drawings and B bitlines 150 extending along a y-axis of the example coordinate system shown (i.e., wordlines 140 are oriented perpendicular to the bitlines 150). Each of FIGS. 3-4 illustrates individual ones of the N capacitors 114 of each of the memory units being stacked above one another along a z-axis of the example coordinate system shown. However, this may be different in other embodiments. In general, in various embodiments, only two or more of the N capacitors 114 of a given memory unit 110 may be stacked above one another along a z-axis, an example of which is illustrated in FIG. 5, described below. FIG. 3 illustrates platelines 160 extending along the y-axis of the example coordinate system shown, i.e., projections of the platelines 160 onto any plane that is parallel the support structure over which the IC device 100 is provided are oriented parallel to the projections of the bitlines 150 onto the same plane and perpendicular to the projections of the wordlines 140 onto the same plane. For that reason, embodiment of FIG. 3 is described as an embodiment where platelines are parallel to bitlines. FIG. 4 illustrates platelines 160 extending along the x-axis of the example coordinate system shown, i.e., projections of the platelines 160 onto any plane that is parallel the support structure over which the IC device 100 is provided are oriented parallel to the projections of the wordlines 140 onto the same plane and perpendicular to the projections of the bitlines 150 onto the same plane. For that reason, embodiment of FIG. 4 is described as an embodiment where platelines are parallel to wordlines.

In some implementations, the relative orientations of wordlines 140, bitlines 150, and platelines 160 as shown in FIGS. 3-4 may be representative of actual physical orientations of these control lines in the actual physical layout of the IC devices 100. For example, in some implementations, the wordlines 140 may indeed be routed as metal lines substantially parallel to one another and substantially perpendicular to the bitlines 150. In another example, in some implementations, the platelines 160 may indeed be routed as metal lines substantially parallel to one another and to the bitlines 150. However, in other implementations, any of the wordlines 140, bitlines 150, and platelines 160 may be oriented in the actual physical layout of the IC devices 100 in any manner that allows realizing the electrical connections as described with reference to FIGS. 3-4.

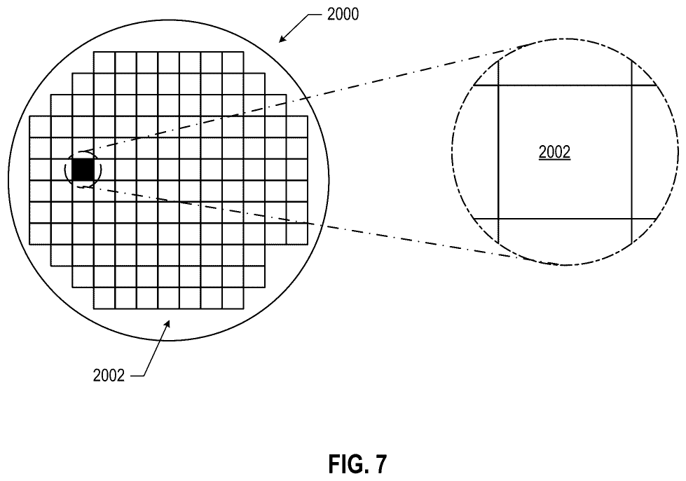

The support structure over which the IC device 100 is provided may, e.g., be the wafer 2000 of FIG. 7, discussed below, and may be, or be included in, a die, e.g., the singulated die 2002 of FIG. 7, discussed below. Such a support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group Ill-V materials (i.e., materials from groups Ill and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure 302 may be a printed circuit board (PCB) substrate. Although a few examples of materials from which the support structure over which the IC device 100 may be formed are described here, any material that may serve as a foundation upon which an IC device implementing memory with one access transistor coupled to multiple capacitors as described herein may be built falls within the spirit and scope of the present disclosure.

FIG. 3 provides an electric circuit diagram of an IC device 300 that is an example of the IC device 100 where each plateline 160 is shared among multiple wordlines 140 and, in each of the memory units 110, N capacitors 114 are coupled to respective (i.e., different) platelines 160, according to some embodiments of the present disclosure. Thus, in the IC device 300, the platelines 160 are parallel to the bitlines 150 and multiple capacitors 114 coupled to a given bitline 150-j are coupled to respective (i.e., different) platelines 160-j1 through 160-jN, as explained in greater detail below.

In the IC device 300, each of the memory units 110 may be implemented as the memory unit 210 of FIG. 2, i.e., where, within a single memory unit 110, N platelines 160 are coupled, in a one-to-one correspondence, to respective ones of the N capacitors 114. For example, as shown in FIG. 3, for the memory unit 110-11 (i.e., an instance of the memory unit 210A that is coupled to the wordline WL₁ and the bitline BL₁, as shown in FIG. 3), a plateline PL₁₁ is coupled to the second capacitor electrode of the capacitor CAP₁, a plateline PL₁₂ is coupled to the second capacitor electrode of the capacitor CAP₂, and so on until a plateline PL_{1N} is coupled to the second capacitor electrode of the capacitor CAP_{N}. In another example, as also shown in FIG. 3, for the memory unit 110-1B (i.e., an instance of the memory unit 210A that is coupled to the wordline WL₁ and the bitline BL_{B}, as shown in FIG. 3), a plateline PL_{B1} is coupled to the second capacitor electrode of the capacitor CAP₁, a plateline PL_{B2} is coupled to the second capacitor electrode of the capacitor CAP₂, and so on until a plateline PL_{BN} is coupled to the second capacitor electrode of the capacitor CAP_{N}.

FIG. 3 illustrates an embodiment where the platelines 160 are parallel to the bitlines 150, meaning that a single plateline 160 is shared among multiple wordlines 140. This is illustrated in FIG. 3 with the plateline PL₁₁, coupled to the second capacitor electrode of the capacitor CAP₁ of the memory unit 110-11, extending further to couple to the second capacitor electrode of the capacitor CAP₁ of other memory units 110 coupled to the same bitline (i.e., the bitline BL₁). For example, FIG. 3 illustrates that the plateline PL₁₁ is also coupled to the second capacitor electrode of the capacitor CAP₁ of the last memory unit 110-W1 coupled to the bitline BL₁ (the memory units 110 between the first and the last memory units coupled to the bitline are not shown in FIG. 3 but are represented by triple dots between the first and the last memory units; the same notation holds for other drawings and other elements of the IC device 100 not specifically shown in FIGS. 3-4). Similarly, the plateline PL₁₂, coupled to the second capacitor electrode of the capacitor CAP₂ of the memory unit 110-11, extends further to couple to the second capacitor electrode of the capacitor CAP₂ of other memory units 110 coupled to the bitline BL₁, and so on, until the plateline PL₁₂ couples to the second capacitor electrode of the capacitor CAP₂ of the last memory unit 110-W1 coupled to the bitline BL₁, as shown in FIG. 3. Furthermore, FIG. 3 illustrates that the plateline PL_{1N}, coupled to the second capacitor electrode of the capacitor CAP_{N} of the memory unit 110-11, extends further to couple to the second capacitor electrode of the capacitor CAP_{N} of other memory units 110 coupled to the bitline BL₁, and so on, until the plateline PL_{1N} couples to the second capacitor electrode of the capacitor CAP_{N} of the last memory unit 110-W1 coupled to the bitline BL₁, as shown in FIG. 3.

Thus, in the IC device 300, corresponding capacitors 114 of the memory units 110 coupled to a single bitline 150-j (i.e., of the memory units 110 that belong to the column j) are coupled to a single plateline 160, where the capacitors 114 of different memory units 110 are described as “corresponding” when they have the same index k identifying them. For example, in the IC device 300, capacitor CAP₁ of the memory unit 110-11, capacitor CAP₁ of the memory unit 110-21, and so on until capacitor CAP₁ of the memory unit 110-W1 are corresponding capacitors, each coupled to the plateline P₁₁ and included in different memory units 110 of column 1; capacitor CAP₂ of the memory unit 110-11, capacitor CAP₂ of the memory unit 110-21, and so on until capacitor CAP₂ of the memory unit 110-W1 are corresponding capacitors, each coupled to the plateline P₁₂ and included in different memory units 110 of column 1; and so on up to capacitor CAP_{N} of the memory unit 110-11, capacitor CAP_{N} of the memory unit 110-21, and so on until capacitor CAP_{N} of the memory unit 110-W1 also being corresponding capacitors, each coupled to the plateline P_{1N} and included in different memory units 110 of column 1. The memory units 110 to which the platelines P₁₁ to P_{1N} of the IC device 300 are coupled are memory units 110 of the column 1 (i.e., memory units 110 coupled to the bitline BL₁). In another example, in the IC device 300, capacitor CAP₁ of the memory unit 110-1B, capacitor CAP₁ of the memory unit 110-2B, and so on until capacitor CAP₁ of the memory unit 110-WB are corresponding capacitors, each coupled to the plateline P_{B1} and included in different memory units 110 of column B; capacitor CAP₂ of the memory unit 110-1B, capacitor CAP₂ of the memory unit 110-2B, and so on until capacitor CAP₂ of the memory unit 110-WB are corresponding capacitors, each coupled to the plateline P_{B2} and included in different memory units 110 of column B; and so on up to capacitor CAP_{N} of the memory unit 110-1B, capacitor CAP_{N} of the memory unit 110-2B, and so on until capacitor CAP_{N} of the memory unit 110-WB also being corresponding capacitors, each coupled to the plateline P_{BN} and included in different memory units 110 of column B. The memory units 110 to which the platelines P_{B1} to P_{BN} of the IC device 300 are coupled are memory units 110 of the column B (i.e., memory units 110 coupled to the bitline BL_{B}). Thus, in the IC device 300, memory units 110 of different columns (i.e., memory units 110 coupled to different bitlines 150) are coupled to respective different sets of N platelines 160. More generally, in the IC device 300, a memory unit 110-ij, coupled to the wordline WLᵢ and to the bitline BLⱼ, is coupled to a set of platelines PLⱼ₁ through PL_{jN}, where, more specifically, each capacitor CAPₖ of the memory unit 110-ij is coupled to a corresponding plateline PLⱼₖ. In such an arrangement, the total number of platelines 160 in the IC device 300 is BxN.

In the IC device 300, each capacitor 114 may be addressed (i.e., selected for READ and WRITE operations) by a unique combination of a wordline WLᵢ, a bitline BLⱼ, and a plateline PLᵢₖ. In the context of the present disclosure, a combination of control lines is described as “unique” when the combination differs from all other combinations in at least one control line being different. For example, in the IC device 300, the capacitor CAP₂ of the memory unit 110-11 may be addressed by a combination of the wordline WL₁ (i.e., i=1), the bitline BL₁ (i.e., j=1), and the plateline PL₁₂ (i.e., j=1 and k=2), while the capacitor CAP₂ of the memory unit 110-W1 may be addressed by a combination of the wordline WL_{W} (i.e., i=W), the bitline BL₁ (i.e., j=1), and the plateline PL₁₂ (i.e., j=1 and k=2). While the bitlines 150 and the platelines 160 in these two combinations are the same (i.e., BL₁ and PL₁₂ for each of the two combinations), the wordlines 140 are different (i.e., WL₁ in the first combination and WL_{W} in the second combination), making these combinations unique with respect to one another. In another example for the IC device 300, the capacitor CAP₂ of the memory unit 110-11 may be addressed by a combination of the wordline WL₁ (i.e., i=1), the bitline BL₁ (i.e., j=1), and the plateline PL₁₂ (i.e., j=1 and k=2), while the capacitor CAP₂ of the memory unit 110-1B may be addressed by a combination of the wordline WL₁ (i.e., i=1), the bitline BL_{B} (i.e., j=B), and the plateline PL_{B2} (i.e., j=B and k=2). While the wordlines 140 in these two combinations are the same (i.e., WL₁ for each of the two combinations), the bitlines 150 and the platelines 160 are different (i.e., respectively, BL₁ and PL₁₂ in the first combination and, respectively, BL_{B} and PL_{B2} in the second combination), making these combinations unique with respect to one another. In yet another example for the IC device 300, the capacitor CAP₂ of the memory unit 110-11 may be addressed by a combination of the wordline WL₁ (i.e., i=1), the bitline BL₁ (i.e., j=1), and the plateline PL₁₂ (i.e., j=1 and k=2), while the capacitor CAP_{N} of the memory unit 110-11 may be addressed by a combination of the wordline WL₁ (i.e., i=1), the bitline BL₁ (i.e., j=1), and the plateline PL_{1N} (i.e., j=1 and k=N). While the wordlines 140 and the bitlines 150 in these two combinations are the same (i.e., WL₁ and BL₁ for each of the two combinations), the platelines 160 are different (i.e., PL₁₂ in the first combination and PL_{1N} in the second combination), making these combinations unique with respect to one another. Having each capacitor 114 of the IC device 100 being addressed by a unique combination of a wordline WLᵢ, a bitline BLⱼ, and a plateline PLⱼₖ, e.g., as is the case with the IC device 300, advantageously allows performing READ and WRITE operations on different memory cells (i.e., on different capacitors 114) independently of one another.

FIG. 4 provides an electric circuit diagram of an IC device 400 where each plateline 160 is shared among multiple bitlines 150 and, in each of the memory units 110, N capacitors 114 are coupled to respective (i.e., different) platelines 160, according to some embodiments of the present disclosure. Thus, in the IC device 400, the platelines 160 are parallel to the wordlines 140 and multiple capacitors 114 coupled to a given wordline 140-i are coupled to respective (i.e., different) platelines 160-i1 through 160-iN, as explained in greater detail below.

In the IC device 400, each of the memory units 110 may be implemented as the memory unit 210 of FIG. 2, i.e., where, within a single memory unit 110, N platelines 160 are coupled, in a one-to-one correspondence, to respective ones of the N capacitors 114. This is similar to the IC device 300, except that FIG. 4 illustrates an embodiment where the platelines 160 are parallel to the wordlines 140, meaning that a single plateline 160 is shared among multiple bitlines 150. This is illustrated in FIG. 4 with the plateline PL₁₁, coupled to the second capacitor electrode of the capacitor CAP₁ of the memory unit 110-11, extending further to couple to the second capacitor electrode of the capacitor CAP₁ of other memory units 110 coupled to the same wordline (i.e., the wordline WL₁). For example, FIG. 4 illustrates that the plateline PL₁₁ is also coupled to the second capacitor electrode of the capacitor CAP₁ of the second memory unit 110-12 coupled to the wordline WL₁ and so on, until the plateline PL₁₁ is also coupled to the second capacitor electrode of the capacitor CAP₁ of the last memory unit 110-1B coupled to the wordline WL₁. Similarly, the plateline PL₁₂, coupled to the second capacitor electrode of the capacitor CAP₂ of the memory unit 110-11, extends further to couple to the second capacitor electrode of the capacitor CAP₂ of other memory units 110 coupled to the wordline WL₁, and so on, until the plateline PL₁₂ couples to the second capacitor electrode of the capacitor CAP₂ of the last memory unit 110-1B coupled to the wordline WL₁, as shown in FIG. 4. Furthermore, FIG. 4 illustrates that that the plateline PL_{1N}, coupled to the second capacitor electrode of the capacitor CAP_{N} of the memory unit 110-11, extends further to couple to the second capacitor electrode of the capacitor CAP_{N} of other memory units 110 coupled to the wordline WL₁, and so on, until the plateline PL_{1N} couples to the second capacitor electrode of the capacitor CAP_{N} of the last memory unit 110-1B coupled to the wordline WL₁.

Thus, in the IC device 400, corresponding capacitors 114 of the memory units 110 coupled to a single wordline 140-i (i.e., of the memory units 110 that belong to the row i) are coupled to a single plateline 160, where, as described above, the capacitors 114 of different memory units 110 are described as “corresponding” when they have the same index k identifying them. For example, in the IC device 400, capacitor CAP₁ of the memory unit 110-11, capacitor CAP₁ of the memory unit 110-12, and so on until capacitor CAP₁ of the memory unit 110-1B are corresponding capacitors, each coupled to the plateline P₁₁ and included in different memory units 110 of row 1; capacitor CAP₂ of the memory unit 110-11, capacitor CAP₂ of the memory unit 110-12, and so on until capacitor CAP₂ of the memory unit 110-1B are corresponding capacitors, each coupled to the plateline P₁₂ and included in different memory units 110 of row 1; and so on up to capacitor CAP_{N} of the memory unit 110-11, capacitor CAP_{N} of the memory unit 110-21, and so on until capacitor CAP_{N} of the memory unit 110-1B also being corresponding capacitors, each coupled to the plateline P_{1N} and included in different memory units 110 of row 1. The memory units 110 to which the platelines P₁₁ to P_{1N} of the IC device 400 are coupled are memory units 110 of the row 1 (i.e., memory units 110 coupled to the wordline WL₁). In another example, in the IC device 400, capacitor CAP₁ of the memory unit 110-W1, capacitor CAP₁ of the memory unit 110-W2, and so on until capacitor CAP₁ of the memory unit 110-WB are corresponding capacitors, each coupled to the plateline P_{W1} and included in different memory units 110 of row W; capacitor CAP₂ of the memory unit 110-W1, capacitor CAP₂ of the memory unit 110-W2, and so on until capacitor CAP₂ of the memory unit 110-WB are corresponding capacitors, each coupled to the plateline P_{W2} and included in different memory units 110 of row W; and so on up to capacitor CAP_{N} of the memory unit 110-W1, capacitor CAP_{N} of the memory unit 110-W2, and so on until capacitor CAP_{N} of the memory unit 110-WB also being corresponding capacitors, each coupled to the plateline P_{WN} and included in different memory units 110 of row W. The memory units 110 to which the platelines P_{W1} to P_{WN} of the IC device 400 are coupled are memory units 110 of the row W (i.e., memory units 110 coupled to the wordline WL_{W}). Thus, in the IC device 400, memory units 110 of different rows (i.e., memory units 110 coupled to different wordlines 140) are coupled to respective different sets of N platelines 160. More generally, in the IC device 400, a memory unit 110-ij, coupled to the wordline WLᵢ and to the bitline BLⱼ, is coupled to a set of platelines PLᵢ₁ through PL_{iN}, where, more specifically, each capacitor CAPₖ of the memory unit 110-ij is coupled to a corresponding plateline PLᵢₖ. In such an arrangement, the total number of platelines 160 in the IC device 400 is WxN.

Similar to the IC device 300, in the IC device 400, each capacitor 114 may be addressed (i.e., selected for READ and WRITE operations) by a unique combination of a wordline WLᵢ, a bitline BLⱼ, and a plateline PLᵢₖ. For example, in the IC device 400, the capacitor CAP₂ of the memory unit 110-11 may be addressed by a combination of the wordline WL₁ (i.e., i=1), the bitline BL₁ (i.e., j=1), and the plateline PL₁₂ (i.e., i=1 and k=2), while the capacitor CAP₂ of the memory unit 110-W1 may be addressed by a combination of the wordline WL_{W} (i.e., i=W), the bitline BL₁ (i.e., j=1), and the plateline PL₁₂ (i.e., i=1 and k=2). While the bitlines 150 and the platelines 160 in these two combinations are the same (i.e., BL₁ and PL₁₂ for each of the two combinations), the wordlines 140 are different (i.e., WL₁ in the first combination and WL_{W} in the second combination), making these combinations unique with respect to one another. In another example for the IC device 400, the capacitor CAP₂ of the memory unit 110-11 may be addressed by a combination of the wordline WL₁ (i.e., i=1), the bitline BL₁ (i.e., j=1), and the plateline PL₁₂ (i.e., i=1 and k=2), while the capacitor CAP₂ of the memory unit 110-W1 may be addressed by a combination of the wordline WL_{W} (i.e., i=W), the bitline BL₁ (i.e., j=1), and the plateline PL_{W2} (i.e., i=W and k=2). While the bitlines 150 in these two combinations are the same (i.e., BL₁ for each of the two combinations), the wordlines 140 and the platelines 160 are different (i.e., respectively, WL₁ and PL₁₂ in the first combination and, respectively, WL_{W} and PL_{W2} in the second combination), making these combinations unique with respect to one another. In yet another example for the IC device 400, the capacitor CAP₂ of the memory unit 110-11 may be addressed by a combination of the wordline WL₁ (i.e., i=1), the bitline BL₁ (i.e., j=1), and the plateline PL₁₂ (i.e., i=1 and k=2), while the capacitor CAP_{N} of the memory unit 110-11 may be addressed by a combination of the wordline WL₁ (i.e., i=1), the bitline BL₁ (i.e., j=1), and the plateline PL_{1N} (i.e., i=1 and k=N). While the wordlines 140 and the bitlines 150 in these two combinations are the same (i.e., WL₁ and BL₁ for each of the two combinations), the platelines 160 are different (i.e., PL₁₂ in the first combination and PL_{1N} in the second combination), making these combinations unique with respect to one another. Having each capacitor 114 of the IC device 100 being addressed by a unique combination of a wordline WLᵢ, a bitline BLⱼ, and a plateline PLᵢₖ, e.g., as is the case with the IC device 400, advantageously allows performing READ and WRITE operations on different memory cells (i.e., on different capacitors 114) independently of one another.

FIGS. 5A and 5B illustrate a cross-sectional side view and a top-down view of an example IC device 500 with an access transistor and multiple capacitors coupled to respective platelines, according to some embodiments of the present disclosure. The IC device 500 includes a support structure 510 and an access transistor 512 provided thereon. The support structure 510 may be a support structure as described with reference to the IC device 100 and may be, e.g., a substrate, a wafer, a die, or a chip. The access transistor 512 has a first S/D region 513-1, a second S/D region 513-2, and a channel region 511 between the first S/D region 513-1 and the second S/D region 513-2. The transistor 512 is an example implementation of the access transistor 112, described above. In particular, the arrangement shown in FIGS. 5A and 5B is an example where a single transistor 512 is coupled to 9 capacitors, labeled as CAP₁ through CAP₉, where each of the 9 capacitors is coupled to a respective plateline, labeled as PL₁₁ through PL₁₉. Thus, the IC device 500 illustrates an example implementation of a memory unit 110-1 as described with reference to FIG. 1, or an example implementation of a memory unit 110-11 as described with reference to FIG. 3 or FIG. 4 (i.e., N=9 for the example shown in FIGS. 5A and 5B), which descriptions are applicable to the IC device 500 and, therefore, in the interests of brevity, are not repeated. Consistent with these descriptions provided above, FIG. 5A illustrates that the second S/D region 513-2 is coupled to an intermediate node 516 (which may be an example of the intermediate node 116, described above) and the intermediate node 516 is then coupled to first capacitor electrodes of each of the 9 capacitors CAP₁ through CAP₉.

In particular, FIG. 5 illustrates an embodiment where multiple platelines may be vertically stacked above one another. For example, FIG. 5 illustrates that platelines PL₁₁ through PL₁₃ is a first sub-set of platelines stacked above one another, platelines PL₁₄ through PL₁₆ is a second sub-set of platelines stacked above one another, and platelines PL₁₇ through PL₁₉ is a third sub-set of platelines stacked above one another. In different embodiments, only one of such subsets may be used (e.g., all of the platelines PL₁₁ through PL₁₉ may be stacked above one another), or different subsets may have different numbers of platelines. Similarly, the capacitors corresponding to respective platelines are also stacked above one another in the same manner as the platelines are divided in subsets and stacked above one another. For example, FIG. 5 illustrates that capacitors CAP₁ through CAP₃ is a first sub-set of capacitors stacked above one another, capacitors CAP₄ through CAP₆ is a second sub-set of capacitors stacked above one another, and capacitors CAP₇ through CAP₉ is a third sub-set of capacitors stacked above one another. As used herein, one element may be described as being “stacked above” another element if a projection of one element onto a plane parallel to a support structure over which the elements are provided at least partially overlaps with a projection of the other element onto that plane. For example, in the IC device 500, the plateline PL₁₂ is stacked above the plateline PL₁₁ above the support structure 510, meaning that a projection of the plateline PL₁₂ onto a plane parallel to the support structure 510 at least partially overlaps with a projection of the plateline PL₁₁ onto the plane. This may be seen from the top-down view shown in FIG. 5B where platelines PL₁₁ through PL₁₃ point to a single element, e.g., the top plateline of the first sub-set (the plateline PL₁₃) because the elements underneath (e.g., platelines PL₁₁ and PL₁₂) the top plateline can't be seen. The same applies to other stacks of platelines of the IC device 500 and other stacks of capacitors or portions thereof. For example, in the IC device 500, a projection of the first capacitor electrode of the capacitor CAP₂ onto a plane parallel to the support structure 510 at least partially overlaps with a projection of the first capacitor electrode of the capacitor CAP₁ onto the plane.

Furthermore, FIG. 5 illustrates an embodiment where first capacitor electrodes of subsets of capacitors stacked above one another are materially continuous. For example, as shown in FIG. 5A, first capacitor electrodes of the capacitors CAP₁ through CAP₃ (i.e., the first sub-set of capacitors) are materially continuous and provided by different portions of a single first structure 520-1 of a first electrically conductive material, first capacitor electrodes of the capacitors CAP₄ through CAP₆ (i.e., the second sub-set of capacitors) are materially continuous and provided by different portions of a single second structure 520-2 of a second electrically conductive material, and first capacitor electrodes of the capacitors CAP₇ through CAP₉ (i.e., the third sub-set of capacitors) are materially continuous and provided by different portions of a single third structure 520-3 of a third electrically conductive material. In various embodiments, the first, second, and third electrically conductive materials may have the same or different material compositions and may include any suitable electrically conductive materials such as copper, aluminum, titanium, cobalt, or any metal alloys. The second capacitor electrodes of various capacitors of the IC device 500 may be provided by portions (e.g., ends) of respective platelines to which the capacitors are coupled. Capacitor insulators of various capacitors are also shown in FIG. 5. For example, in some embodiments, each of the capacitors of the first sub-set may include a first capacitor insulator 518-1 between its first and second capacitor electrodes, each of the capacitors of the second sub-set may include a second capacitor insulator 518-2, and each of the capacitors of the third sub-set may include a third capacitor insulator 518-1. In various embodiments, the first, second, and third capacitor insulators 518 may have the same or different material compositions and may include any suitable capacitor insulator materials, such as any of the materials described with reference to the capacitor insulator 118.

In some embodiments, the intermediate node 516 may be implemented as a conductive via having a first end and a second end, wherein the first end of the via is coupled (e.g., directly connected) to the second S/D region 513-2 of the access transistor 512 and the second end of the via is coupled (e.g., directly connected) to an electrically conductive material of the first structure 520-1 extending away from the support structure 510, where different portions of the electrically conductive material of the first structure 520-1 are the first capacitor electrodes of the capacitors CAP₁ through CAP₃ (i.e., of the first sub-set of capacitors). FIG. 5A further illustrates an electrically conductive structure 530 that may serve to provide electrical connectivity between the electrically conductive material of the first structure 520-1, the electrically conductive material of the second structure 520-2, and electrically conductive material of the third structure 520-3. The implementation of the electrically conductive structure 530 shown in FIG. 5A is just one of many possible implementations of how the structures 520 may be electrically connected to one another; other implementations are possible and are within the scope of the present disclosure (e.g., in some embodiments, the electrically conductive structure 530 may be provided below the stacks of platelines of the IC device 500). FIG. 5B does not illustrate the electrically conductive structure 530 in order to not clutter the drawing.

As shown in FIG. 5A, for a given stack of platelines (e.g., for the platelines of one of the subsets of platelines), different platelines of the stack are provided in different layers above the support structure 510. In some embodiments, these different layers may be different metal layers of a metallization stack of the IC device 500. As shown in FIG. 5B, platelines of different stacks may be substantially parallel to one another. Thus, in the view of FIG. 5A, the platelines and the capacitors of the second and third subsets are actually behind the plane of the drawing in which the platelines and the capacitors of the first sub-set would be seen, but they are shown anyway to illustrate how they are arranged with respect to one another. In some embodiments, as shown in FIG. 5A, the first structure 520-1 may be substantially aligned along the x-axis of the example coordinate system shown with the second S/D region 513-2. In some embodiments, as also shown in FIG. 5A, the third structure 520-3 may be substantially aligned along the x-axis of the example coordinate system shown with the first S/D region 513-1.

FIG. 5A further illustrates vias 540-11, 540-12, and 540-13, which may be used to provide electrical connectivity to, respectively, the platelines PL₁₁, PL₁₂, and PL₁₃. In some embodiments, the platelines of a given sub-set of platelines may be arranged in a staircase arrangement as shown in FIG. 5A in order to be able to provide a particularly dense arrangement of vias 540 connecting to them. Platelines of other sub-set of platelines of the IC device 500 may include analogous vias 540 but at different locations along the y-axis of the example coordinate system shown.

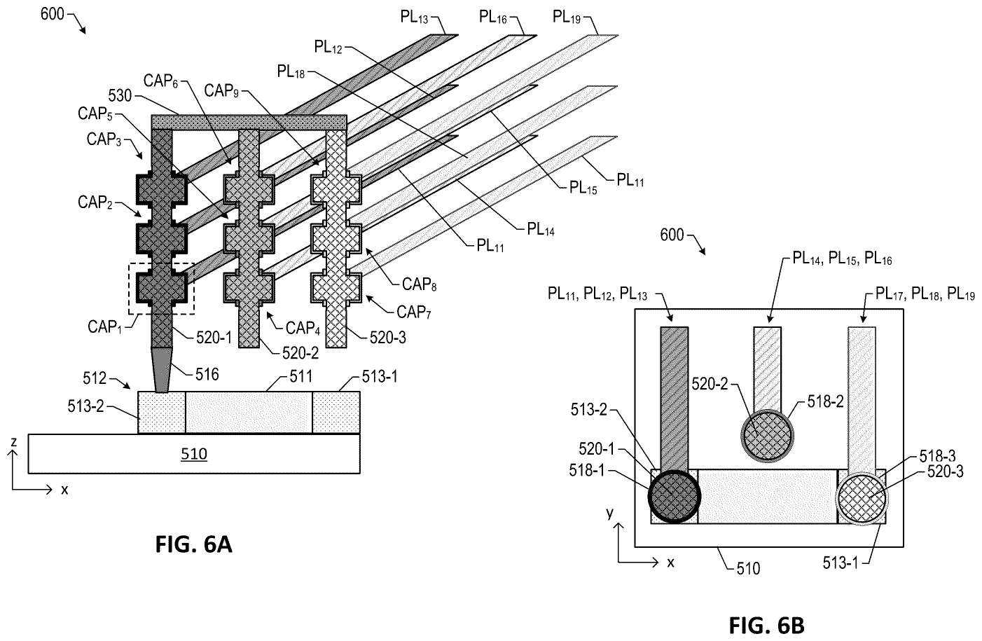

FIGS. 6A and 6B illustrate a cross-sectional side view and a top-down view of an example IC device 600 with an access transistor and multiple capacitors coupled to respective platelines, according to other embodiments of the present disclosure. The IC device 600 is substantially the same as the IC device 500, described above, except that the platelines PL₁₁ through PL₁₉ extend along the y-axis in the IC device 600, whereas in the IC device they extended along the x-axis. Therefore, while FIG. 6A is still mainly a cross-sectional side view, it also shows in the back the various platelines PL₁₁ through PL₁₉ which actually extend out of the plane of the drawing of FIG. 6A. Other descriptions provided with respect to the IC device 500 are applicable to the IC device 600 and, therefore, in the interests of brevity, are not repeated.

Various arrangements of the IC device 100 as illustrated in FIGS. 3-6 do not represent an exhaustive set of IC devices that may implement memory with one access transistor coupled to multiple capacitors as described herein, but merely provide examples of such devices/structures/assemblies. In particular, the number and positions of various elements shown in FIGS. 3-4 is purely illustrative and, in various other embodiments, other numbers of these elements, provided in other locations relative to one another may be used in accordance with the general architecture considerations described herein.

Arrangements with one or more IC devices implementing memory with one access transistor coupled to multiple capacitors as disclosed herein may be included in any suitable electronic device. FIGS. 7-11 illustrate various examples of devices and components that may include one or more IC devices implementing memory with one access transistor coupled to multiple capacitors as disclosed herein.

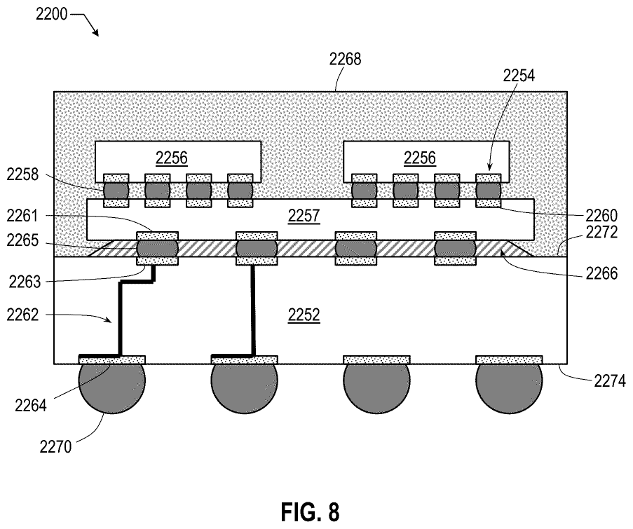

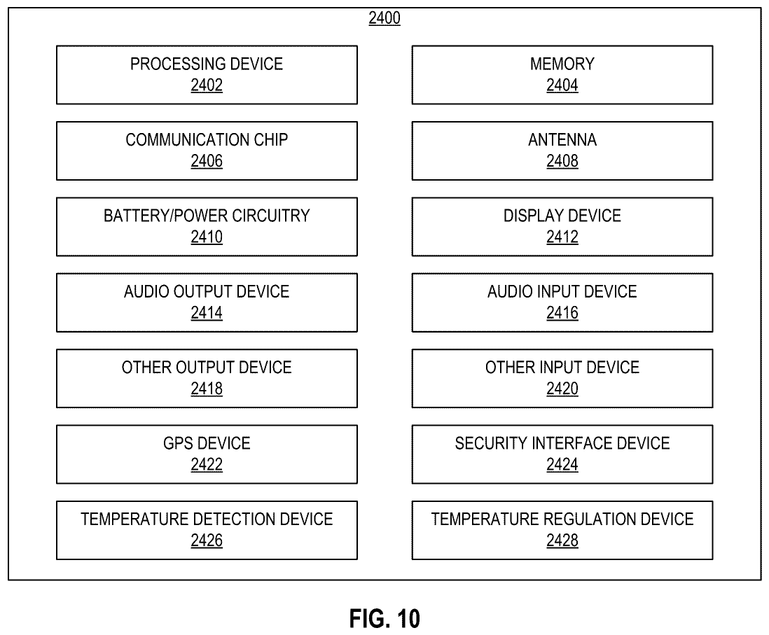

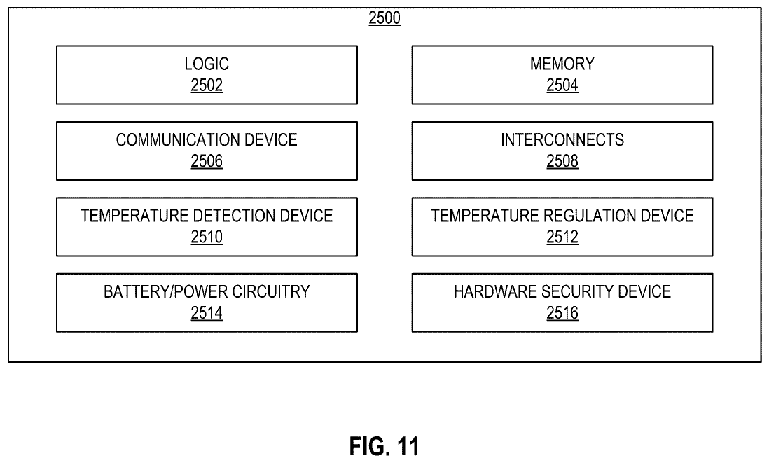

FIG. 7 illustrates top views of a wafer 2000 and dies 2002 that may include one or more IC devices implementing memory with one access transistor coupled to multiple capacitors in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 8. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more IC devices implementing memory with one access transistor coupled to multiple capacitors as described herein). After the fabrication of the semiconductor product is complete (e.g., after manufacture of any embodiment of the IC device 100 as described herein), the wafer 2000 may undergo a singulation process in which each of the dies 2002 is separated from one another to provide discrete “chips” of the semiconductor product. In particular, devices that include one or more IC devices implementing memory with one access transistor coupled to multiple capacitors as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., a memory device with one access transistor coupled to multiple capacitors as described herein), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 10 or the logic 2502 of FIG. 11) or other logic that is configured to store information in the memory devices or execute instructions stored in the memory array.

FIG. 8 is a side, cross-sectional view of an example IC package 2200 that may include one or more IC devices implementing memory with one access transistor coupled to multiple capacitors in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 8 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 8 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

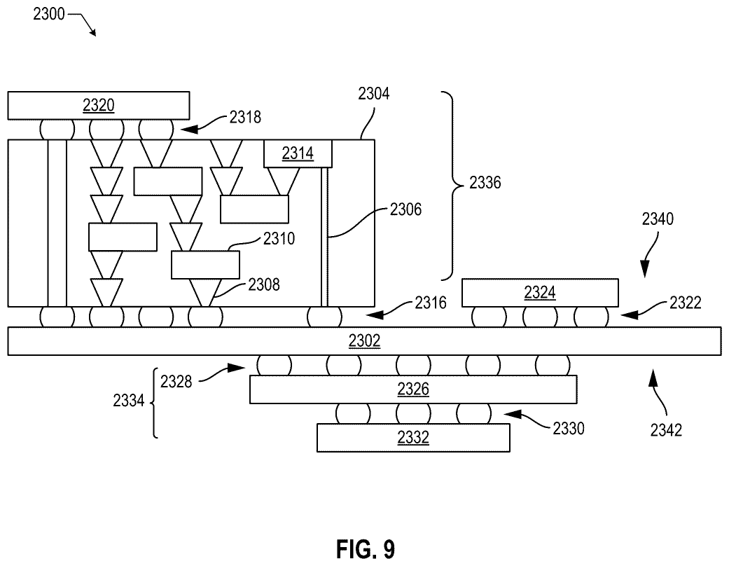

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 8 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 9.

The dies 2256 may take the form of any of the embodiments of the die 2002 discussed herein (e.g., may include any of the embodiments of the IC devices implementing memory with one access transistor coupled to multiple capacitors as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more IC devices implementing memory with one access transistor coupled to multiple capacitors, e.g., as discussed above; in some embodiments, at least some of the dies 2256 may not include any IC devices implementing memory with one access transistor coupled to multiple capacitors.

The IC package 2200 illustrated in FIG. 8 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 8, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 9 is a cross-sectional side view of an IC device assembly 2300 that may include components having one or more IC devices implementing memory with one access transistor coupled to multiple capacitors in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more IC devices implementing memory with one access transistor coupled to multiple capacitors in accordance with any of the embodiments disclosed herein; e.g., any of the IC packages discussed below with reference to the IC device assembly 2300 may take the form of any of the embodiments of the IC package 2200 discussed above with reference to FIG. 8 (e.g., may include one or more IC devices implementing memory with one access transistor coupled to multiple capacitors provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 9 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 9), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 7), an IC device, or any other suitable component. In particular, the IC package 2320 may include one or more IC devices implementing memory with one access transistor coupled to multiple capacitors as described herein. Although a single IC package 2320 is shown in FIG. 9, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 9, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group Ill-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 9 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 10 is a block diagram of an example computing device 2400 that may include one or more components including memory with one access transistor coupled to multiple capacitors in accordance with any of the embodiments disclosed herein. For example, any suitable ones of the components of the computing device 2400 may include a die (e.g., the die 2002 of FIG. 7) having one or more memory units with one access transistor coupled to multiple capacitors as described herein. Any one or more of the components of the computing device 2400 may include, or be included in, an IC package 2200 of FIG. 8 or an IC device 2300 of FIG. 9.

A number of components are illustrated in FIG. 10 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC die.

Additionally, in various embodiments, the computing device 2400 may not include one or more of the components illustrated in FIG. 10, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM. In some embodiments, the memory 2404 may include one or more memory units with one access transistor coupled to multiple capacitors as described herein.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 11 is a block diagram of an example processing device 2500 that may include one or more memory units with one access transistor coupled to multiple capacitors in accordance with any of the embodiments disclosed herein. For example, any suitable ones of the components of the processing device 2500 may include a die (e.g., the die 2002 of FIG. 7) having one or more memory units with one access transistor coupled to multiple capacitors as described herein. Any one or more of the components of the processing device 2500 may include, or be included in, an IC device 2300 (FIG. 9). Any one or more of the components of the processing device 2500 may include, or be included in, an IC package 2200 of FIG. 8 or an IC device 2300 of FIG. 9. Any one or more of the components of the processing device 2500 may include, or be included in, a computing device 2400 of FIG. 10; for example, the processing device 2500 may be the processing device 2402 of the computing device 2400.

A number of components are illustrated in FIG. 11 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 11, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 10). In some embodiments, the memory 2504 may be a designated device configured to provide storage functionality for the components of the processing device 2500 (e.g., local), while the memory 1604 may be configured to provide system-level storage functionality for the entire computing device 2400 (e.g., global). In some embodiments, the memory 2504 may include memory that shares a die with the logic circuitry 2502. In some embodiments, the memory 2504 may include one or more memory units with one access transistor coupled to multiple capacitors as described herein.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, e.g., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 10). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, MIM structures, etc.

The processing device 2500 may include a temperature detection device 2510 which may be implemented substantially as described above with reference to the temperature detection device 2426 of FIG. 10 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 10 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 10. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 10. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example A1 provides an IC device that includes a support structure (e.g., a substrate, a wafer, a die, or a chip); a transistor over the support structure, the transistor having a region, where the region is either a source region or a drain region; a first plateline and a second plateline over the support structure; a first capacitor, where a first capacitor electrode of the first capacitor is coupled (e.g., directly connected) to the region, and a second capacitor electrode of the first capacitor is coupled (e.g., directly connected) to the first plateline; and a second capacitor, where a first capacitor electrode of the second capacitor is coupled (e.g., directly connected) to the region, and a second capacitor electrode of the second capacitor is coupled (e.g., directly connected) to the second plateline, where the first plateline is between the support structure and the second plateline, and the first capacitor electrode of the first capacitor is materially continuous with the first capacitor electrode of the second capacitor.

Example A2 provides the IC device according to example A1, where the second plateline is stacked above the first plateline above the support structure.

Example A3 provides the IC device according to examples A1 or A2, where a projection of the second plateline onto a plane parallel to the support structure at least partially overlaps with a projection of the first plateline onto the plane.

Example A4 provides the IC device according to any one of the preceding examples A, where a projection of the first capacitor electrode of the second capacitor onto a plane parallel to the support structure at least partially overlaps with a projection of the first capacitor electrode of the first capacitor onto the plane.

Example A5 provides the IC device according to any one of the preceding examples A, further including a conductive via having a first end and a second end, where the first end of the via is coupled (e.g., directly connected) to the region, and the second end of the via is coupled (e.g., directly connected) to an electrically conductive material extending away from the support structure, where a first portion of the electrically conductive material is the first capacitor electrode of the first capacitor and a second portion of the electrically conductive material is the first capacitor electrode of the second capacitor.

Example A6 provides the IC device according to example A5, where the first portion and the second portion are materially continuous portions of the electrically conductive material.

Example A7 provides the IC device according to any one of the preceding examples A, further including: a third plateline and a fourth plateline over the support structure; a third capacitor, where a first capacitor electrode of the third capacitor is coupled (e.g., directly connected) to the region, and a second capacitor electrode of the third capacitor is coupled (e.g., directly connected) to the third plateline; and a fourth capacitor, where a first capacitor electrode of the fourth capacitor is coupled (e.g., directly connected) to the region, and a second capacitor electrode of the fourth capacitor is coupled (e.g., directly connected) to the fourth plateline, where: the third plateline is between the support structure and the fourth plateline, and the first capacitor electrode of the third capacitor is materially continuous with the first capacitor electrode of the fourth capacitor.

Example A8 provides the IC device according to example A7, where the first capacitor electrode of the third capacitor is further materially continuous with the first capacitor electrode of the first capacitor and the first capacitor electrode of the second capacitor.

Example A9 provides the IC device according to examples A7 or A8, where the fourth plateline is stacked above the third plateline above the support structure.

Example A10 provides the IC device according to any one of examples A7-A9, where a projection of the fourth plateline onto a plane parallel to the support structure at least partially overlaps with a projection of the third plateline onto the plane.

Example A11 provides the IC device according to example A10, where a projection of the second plateline onto the plane at least partially overlaps with a projection of the first plateline onto the plane, and the projection of the second plateline onto the plane is parallel to the projection of the fourth plateline onto the plane.

Example A12 provides the IC device according to example A11, further including: a fifth plateline over the support structure; and a fifth capacitor, where a first capacitor electrode of the fifth capacitor is coupled (e.g., directly connected) to the region, and a second capacitor electrode of the fifth capacitor is coupled (e.g., directly connected) to the fifth plateline, where a projection of the fifth plateline onto the plane is parallel to the projection of the fourth plateline onto the plane.

Example A13 provides the IC device according to example A12, where the projection of the fourth plateline onto the plane is between the projection of the second plateline onto the plane and the projection of the fifth plateline onto the plane.

Example A14 provides the IC device according to example A13, where: the region is a first region, the transistor further includes a second region, one of the first region and the second region is the source region and another one of the first region and the second region is the drain region of the transistor, and a projection of the second region onto the plane at least partially overlaps with the projection of the fifth plateline onto the plane.

Example A15 provides the IC device according to example A14, where a projection of the first region onto the plane at least partially overlaps with the projection of the second plateline onto the plane.

Example A16 provides the IC device according to any one of examples A7-A15, where, where a projection of the first capacitor electrode of the fourth capacitor onto a plane parallel to the support structure at least partially overlaps with a projection of the first capacitor electrode of the third capacitor onto the plane.

Example A17 provides an IC device that includes a support structure (e.g., a substrate, a wafer, a die, or a chip); a transistor over the support structure, the transistor having a region, where the region is either a source region or a drain region; a metallization stack over the transistor, the metallization stack including a first metal layer and a second metal layer; first and second electrically conductive structures extending through the first metal layer and the second metal layer; and first, second, third, and fourth electrically conductive lines, where: the first electrically conductive line and the third electrically conductive line are in the first metal layer, the second electrically conductive line and the fourth electrically conductive line are in the second metal layer, the first electrically conductive structure is a first capacitor electrode of each of a first capacitor and a second capacitor, the second electrically conductive structure is a first capacitor electrode of each of a third capacitor and a fourth capacitor, the first electrically conductive line is a second capacitor electrode of the first capacitor, the second electrically conductive line is a second capacitor electrode of the second capacitor, the third electrically conductive line is a second capacitor electrode of the third capacitor, and the fourth electrically conductive line is a second capacitor electrode of the fourth capacitor.

Example A18 provides the IC device according to example A17, where the second electrically conductive line is stacked above the first electrically conductive line, and the fourth electrically conductive line is stacked above the third electrically conductive line, and where the first electrically conductive line and the third electrically conductive line are parallel.

Example A19 provides an IC device that includes a support structure (e.g., a substrate, a wafer, a die, or a chip); a transistor over the support structure, the transistor having a region, where the region is either a source region or a drain region; a first set of two or more capacitors in different layers above the transistor; and a second set of two or more capacitors in different layers above the transistor, where first capacitor electrodes of the first set of two or more capacitors and of the second set of two or more capacitors are coupled (e.g., directly connected) to the region, and second capacitor electrodes of the first set of two or more capacitors and of the second set of two or more capacitors are coupled (e.g., directly connected) to different electrically conductive lines.

Example A20 provides the IC device according to example A19, where the first capacitor electrodes of the first set of two or more capacitors and of the second set of two or more capacitors are different portions of an electrically continuous electrically conductive material.

Example B1 provides an IC device that includes W wordlines, where a wordline WLᵢ is any of the W wordlines where i is an integer between 1 and W; B bitlines, where a bitline BLⱼ is any of the B bitlines where j is an integer between 1 and B; and M memory units, where a memory unit MUᵢⱼ is a memory unit of the M memory units that is coupled to the wordline WLᵢ and the bitline BLⱼ, and where the memory unit MUᵢⱼ includes an access transistor Tᵢⱼ, and N hysteretic capacitors coupled to the access transistor Tᵢⱼ, where a capacitor CAPₖ is any of the N hysteretic capacitors where k is an integer between 1 and N. The IC device of example B1 further includes P platelines, where a plateline PLⱼₖ is a plateline of the P platelines that is coupled to the capacitor CAPₖ of the memory unit MUᵢⱼ that is coupled to the bitline BLⱼ.

Example B2 provides the IC device according to example B1, where N different platelines of the P platelines are coupled to each sub-set of memory units that are coupled to one of the B bitlines.

Example B3 provides the IC device according to examples B1 or B2, where the plateline PLⱼₖ is coupled to the capacitor CAPₖ of each memory unit of a sub-set of memory units that are coupled to the bitline BLⱼ.

Example B4 provides the IC device according to example B3, where the sub-set of memory units that are coupled to the bitline BLⱼ includes W memory units.

Example B5 provides the IC device according to examples B3 or B4, where the sub-set of memory units that are coupled to the bitline BLⱼ is one of B subsets of memory units.

Example B6 provides the IC device according to any one of examples B1-B5, where P=BxN.

Example B7 provides the IC device according to any one of examples B1-B6, where each of the N hysteretic capacitors is coupled to a different (i.e., unique) combination of one of the W wordlines, one of the B bitlines, and one of the P platelines.

Example B8 provides an IC device that includes W wordlines, where a wordline WLᵢ is any of the W wordlines where i is an integer between 1 and W; B bitlines, where a bitline BLⱼ is any of the B bitlines where j is an integer between 1 and B; M memory units, where a memory unit MUᵢⱼ is a memory unit of the M memory units that is coupled to the wordline WLᵢ and the bitline BLⱼ, and where the memory unit MUᵢⱼ includes an access transistor Tᵢⱼ, and N hysteretic capacitors coupled to the access transistor Tᵢⱼ, where a capacitor CAPₖ is any of the N hysteretic capacitors where k is an integer between 1 and N; and P platelines, where a plateline PLᵢₖ is a plateline of the P platelines that is coupled to the capacitor CAPₖ of the memory unit MUᵢⱼ that is coupled to the wordline WLᵢ.

Example B9 provides the IC device according to example B8, where N different platelines of the P platelines are coupled to each sub-set of memory units that are coupled to one of the W wordlines.

Example B10 provides the IC device according to examples B8 or B9, where the plateline PLᵢₖ is coupled to the capacitor CAPₖ of each memory unit of a sub-set of memory units that are coupled to the wordline WLᵢ.

Example B11 provides the IC device according to example B10, where the sub-set of memory units that are coupled to the wordline WLᵢ includes B memory units.

Example B12 provides the IC device according to examples B10 or B11, where the sub-set of memory units that are coupled to the wordline WLᵢ is one of W subsets of memory units.

Example B13 provides the IC device according to any one of examples B8-B12, where P=WxN.

Example B14 provides the IC device according to any one of examples B8-B13, where each of the N hysteretic capacitors is coupled to a different (i.e., unique) combination of one of the W wordlines, one of the B bitlines, and one of the P platelines.

Example 21 provides the IC device according any one of examples A1-A20 or B1-B14, wherein a capacitor insulator of any of the capacitors of examples A1-A20 or B1-B14 includes a hysteretic material, and wherein the hysteretic material includes a ferroelectric (FE) or an antiferroelectric (AFE) material.

Example 22 provides the IC device according to example 21, where the FE or the AFE material includes a material at least 5% of which is in an orthorhombic phase and/or a tetragonal phase, the material including one or more of a material including hafnium, zirconium, and oxygen, a material including silicon, hafnium, and oxygen, a material including germanium, hafnium, and oxygen, a material including aluminum, hafnium, and oxygen, a material including yttrium, hafnium, and oxygen, a material including lanthanum, hafnium, and oxygen, a material including gadolinium, hafnium, and oxygen, and a material including niobium, hafnium, and oxygen.

Example 23 provides the IC device according to any one of examples A1-A20 or B1-B14, wherein a capacitor insulator of any of the capacitors of examples A1-A20 or B1-B14 includes a hysteretic arrangement, and where the hysteretic arrangement includes a stack of at alternating layers of a material that includes silicon and oxygen and a material that includes silicon and nitrogen.

Example 24 provides the IC device according to example 23, where the hysteretic arrangement includes a stack of a first layer, a second layer, and a third layer, the first layer includes a first insulator material, the second layer includes an electrically conductive material or a semiconductor, and the third layer includes a second insulator material.

Example 25 provides the IC device according to example 24, where a least one of the first insulator material and the second insulator material is a material that includes silicon and oxygen (e.g., silicon oxide), and the second layer includes a material that includes silicon and nitrogen (e.g., silicon nitride).

Example 26 provides an IC package that includes an IC device according to any one of the preceding examples; and a further IC component, coupled to the IC device.

Example 27 provides the IC package according to example 26, where the further component includes one of a package substrate and an interposer.

Example 28 provides the IC package according to example 26, where the further component is a further IC die.

Example 29 provides the IC package according to any one of examples 26-28, where the IC device includes, or is a part of, at least one of a memory device, a computing device, a wearable device, a handheld electronic device, and a wireless communications device.

Example 30 provides an electronic device that includes a carrier substrate; and one or more of the IC device according to any one of the preceding examples and the IC package according to any one of the preceding examples, coupled to the carrier substrate.

Example 31 provides the electronic device according to example 30, where the carrier substrate is a motherboard.

Example 32 provides the electronic device according to example 30, where the carrier substrate is a PCB.

Example 33 provides the electronic device according to any one of examples 30-32, where the electronic device is a wearable electronic device (e.g., a smart watch) or handheld electronic device (e.g., a mobile phone).

Example 34 provides the electronic device according to any one of examples 30-33, where the electronic device further includes one or more communication chips and an antenna.

Example 35 provides the electronic device according to any one of examples 30-34, where the electronic device is an RF transceiver.

Example 36 provides the electronic device according to any one of examples 30-34, where the electronic device is one of a switch, a power amplifier, a low-noise amplifier, a filter, a filter bank, a duplexer, an upconverter, or a downconverter of an RF communications device, e.g., of an RF transceiver.

Example 37 provides the electronic device according to any one of examples 30-34, where the electronic device is a computing device.

Example 38 provides the electronic device according to any one of examples 30-37, where the electronic device is included in a base station of a wireless communication system.

Example 39 provides the electronic device according to any one of examples 30-37, where the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a transistor over a support structure, the transistor having a region, wherein the region is either a source region or a drain region;
a first plateline and a second plateline;
a first capacitor, wherein a first capacitor electrode of the first capacitor is coupled to the region, and a second capacitor electrode of the first capacitor is coupled to the first plateline; and
a second capacitor, wherein a first capacitor electrode of the second capacitor is coupled to the region, and a second capacitor electrode of the second capacitor is coupled to the second plateline,
wherein the first plateline is between the support structure and the second plateline, and the first capacitor electrode of the first capacitor is materially continuous with the first capacitor electrode of the second capacitor.

2. The IC device according to claim 1, wherein the second plateline is stacked above the first plateline above the support structure.

3. The IC device according to claim 1, wherein a projection of the second plateline onto a plane parallel to the support structure at least partially overlaps with a projection of the first plateline onto the plane.

4. The IC device according to claim 1, wherein a projection of the first capacitor electrode of the second capacitor onto a plane parallel to the support structure at least partially overlaps with a projection of the first capacitor electrode of the first capacitor onto the plane.

5. The IC device according to claim 1, further comprising a conductive via having a first end and a second end, wherein the first end of the conductive via is coupled to the region, and the second end of the conductive via is coupled to an electrically conductive material extending away from the support structure, wherein a first portion of the electrically conductive material is the first capacitor electrode of the first capacitor and a second portion of the electrically conductive material is the first capacitor electrode of the second capacitor.

6. The IC device according to claim 5, wherein the first portion and the second portion are materially continuous portions of the electrically conductive material.

7. The IC device according to claim 1, further comprising:
a third plateline and a fourth plateline over the support structure;
a third capacitor, wherein a first capacitor electrode of the third capacitor is coupled to the region, and a second capacitor electrode of the third capacitor is coupled to the third plateline; and
a fourth capacitor, wherein a first capacitor electrode of the fourth capacitor is coupled to the region, and a second capacitor electrode of the fourth capacitor is coupled to the fourth plateline,
wherein:
the third plateline is between the support structure and the fourth plateline, and
the first capacitor electrode of the third capacitor is materially continuous with the first capacitor electrode of the fourth capacitor.

8. The IC device according to claim 7, wherein the first capacitor electrode of the third capacitor is further materially continuous with the first capacitor electrode of the first capacitor and the first capacitor electrode of the second capacitor.

9. The IC device according to claim 7, wherein the fourth plateline is stacked above the third plateline above the support structure.

10. The IC device according to claim 7, wherein a projection of the fourth plateline onto a plane parallel to the support structure at least partially overlaps with a projection of the third plateline onto the plane.

11. The IC device according to claim 10, wherein:
a projection of the second plateline onto the plane at least partially overlaps with a projection of the first plateline onto the plane, and
the projection of the second plateline onto the plane is parallel to the projection of the fourth plateline onto the plane.

12. The IC device according to claim 11, further comprising:
a fifth plateline over the support structure; and
a fifth capacitor, wherein a first capacitor electrode of the fifth capacitor is coupled to the region, and a second capacitor electrode of the fifth capacitor is coupled to the fifth plateline,
wherein a projection of the fifth plateline onto the plane is parallel to the projection of the fourth plateline onto the plane.

13. The IC device according to claim 12, wherein the projection of the fourth plateline onto the plane is between the projection of the second plateline onto the plane and the projection of the fifth plateline onto the plane.

14. The IC device according to claim 13, wherein:
the region is a first region,
the transistor further includes a second region,
one of the first region and the second region is the source region and another one of the first region and the second region is the drain region of the transistor, and
a projection of the second region onto the plane at least partially overlaps with the projection of the fifth plateline onto the plane.

15. The IC device according to claim 14, wherein a projection of the first region onto the plane at least partially overlaps with the projection of the second plateline onto the plane.

16. The IC device according to claim 7, wherein, wherein a projection of the first capacitor electrode of the fourth capacitor onto a plane parallel to the support structure at least partially overlaps with a projection of the first capacitor electrode of the third capacitor onto the plane.

17. An integrated circuit (IC) device, comprising:
a transistor over a substrate, the transistor having a region, wherein the region is either a source region or a drain region;
a metallization stack over the transistor, the metallization stack comprising a first metal layer and a second metal layer;
first and second electrically conductive structures extending through the first metal layer and the second metal layer; and
first, second, third, and fourth electrically conductive lines, wherein:
the first electrically conductive line and the third electrically conductive line are in the first metal layer,
the second electrically conductive line and the fourth electrically conductive line are in the second metal layer,
the first electrically conductive structure is a first capacitor electrode of a first capacitor and a second capacitor,
the second electrically conductive structure is a first capacitor electrode of a third capacitor and a fourth capacitor,
the first electrically conductive line is a second capacitor electrode of the first capacitor,
the second electrically conductive line is a second capacitor electrode of the second capacitor,
the third electrically conductive line is a second capacitor electrode of the third capacitor, and
the fourth electrically conductive line is a second capacitor electrode of the fourth capacitor.

18. The IC device according to claim 17, wherein the second electrically conductive line is stacked above the first electrically conductive line, and the fourth electrically conductive line is stacked above the third electrically conductive line, and wherein the first electrically conductive line and the third electrically conductive line are parallel.

19. An integrated circuit (IC) device, comprising:
a die;
a transistor on the die, the transistor having a region, wherein the region is either a source region or a drain region;
a first set of two or more capacitors in different layers above the transistor; and
a second set of two or more capacitors in different layers above the transistor,
wherein first capacitor electrodes of the first set of two or more capacitors and of the second set of two or more capacitors are coupled to the region, and second capacitor electrodes of the first set of two or more capacitors and of the second set of two or more capacitors are coupled to different electrically conductive lines.

20. The IC device according to claim 19, wherein the first capacitor electrodes of the first set of two or more capacitors and of the second set of two or more capacitors are different portions of an electrically continuous electrically conductive material.
